(19) United States
(12) Patent Application Publication
(10) Pub. No.: US 2024/0297111 A1
(43) Pub. Date: Sep. 5, 2024

(54) CARRIER STRUCTURE, PACKAGE ARRANGEMENT, METHOD OF FORMING A CARRIER STRUCTURE, AND METHOD OF FORMING A PACKAGE ARRANGEMENT

(71) Applicant: Infineon Techologies AG, Neubiberg (DE)

(72) Inventors: Martin MAYER, Neukirchen bei Sulzbach-Rosenberg (DE); Christian KASZTELAN, Budapeste (HU); Qun YE, Singapore (SG); Alexander HEINRICH, Bad Abbach (DE)

(73) Assignee: Infineon Technologies AG, Neubiberg (DE)

(21) Appl. No.: 18/593,309

(22) Filed: Mar. 1, 2024

(30) Foreign Application Priority Data
Mar. 3, 2023 (DE) 10 2023 105 321.3

(51) Int. Cl. H01L 23/498; H01L 23/29; H01L 23/31

(52) U.S. Cl. CPC H01L 23/49894; H01L 23/291; H01L 23/293; H01L 23/3171; H01L 23/49838; H01L 23/49861

(57) ABSTRACT

A carrier structure is provided. The carrier structure may include an electrically insulating carrier, wherein the carrier is thermally conductive. The carrier includes a core of an electrically insulating material, a first metal layer applied to a first side of the core, and a second metal layer applied to a second side of the core, wherein the second side is opposite the first side. A first exposed solder layer is located on the first metal layer, and a second exposed solder layer is located on the second metal layer.

### CROSS-REFERENCE TO RELATED APPLICATION

This Utility Patent Application claims priority to German Patent Application No. 10 2023 105 321.3 filed Mar. 3, 2023, which is incorporated herein by reference.

### TECHNICAL FIELD

Various embodiments relate generally to a carrier structure, a package arrangement, a method of forming a carrier structure, and a method of forming a package arrangement.

### BACKGROUND

At present, manufacturers of package arrangements who are not willing to invest into advanced insulation products need to provide an (electrical) insulation of their product themselves. Many possibilities are on the market for this purpose. For example, many suppliers offer insulation foils. These foils provide only limited thermal conductivity, even when new. Furthermore, their insulation strength may possibly be reduced during their lifetime.

Another option is to use simple bare ceramic to ensure insulation. In order to ensure a good thermal contact, thermal grease may be used between a device, e. g., a chip package, and the ceramic. An interface between ceramic and cooler may additionally be filled up with thermal grease.

Thermal conductivity of the thermal grease may be limited to very low values, and the thermal grease may possibly dry out during its lifetime, which may possibly result in losing its (thermal) performance. Heat transfer may therefore always be critical.

### SUMMARY

A carrier structure is provided. The carrier structure may include an electrically insulating carrier, wherein the carrier is thermally conductive, the carrier including a core of an electrically insulating material, a first metal layer applied to a first side of the core, and a second metal layer applied to a second side of the core, wherein the second side is opposite the first side, a first exposed solder layer on the first metal layer, and a second exposed solder layer on the second metal layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic cross-sectional view of a carrier structure in accordance with various embodiments;

FIG. 2A shows a schematic cross-sectional view of a package arrangement in accordance with various embodiments;

FIG. 2B shows a schematic cross-sectional view of a package arrangement according to a prior art;

FIG. 3 shows a schematic cross-sectional, partially exploded view of a package arrangement in accordance with various embodiments;

each of FIGS. 4A and 4B shows a schematic cross-sectional view of a package arrangement in accordance with various embodiments;

each of FIGS. 4C and 4D shows a schematic cross-sectional view of a package arrangement in accordance with various embodiments;

FIG. 5 shows a flow diagram of a method of forming a carrier structure in accordance with various embodiments; and

FIG. 6 shows a flow diagram of a method of forming a package arrangement in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

As described above, some chip packages, in particular high power chip packages that generate a large amount of heat during operation, may require both, efficient cooling, e. g., via a heat sink, and electrical insulation (from the heat sink) at the same time.

Different techniques of attaching a chip package to the heat sink are presently used.

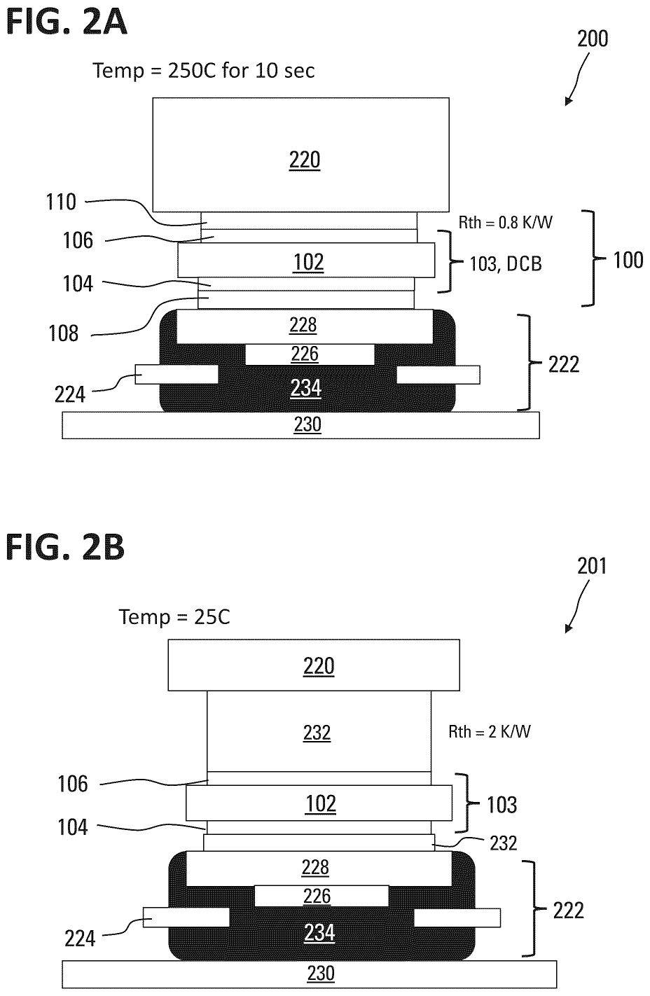

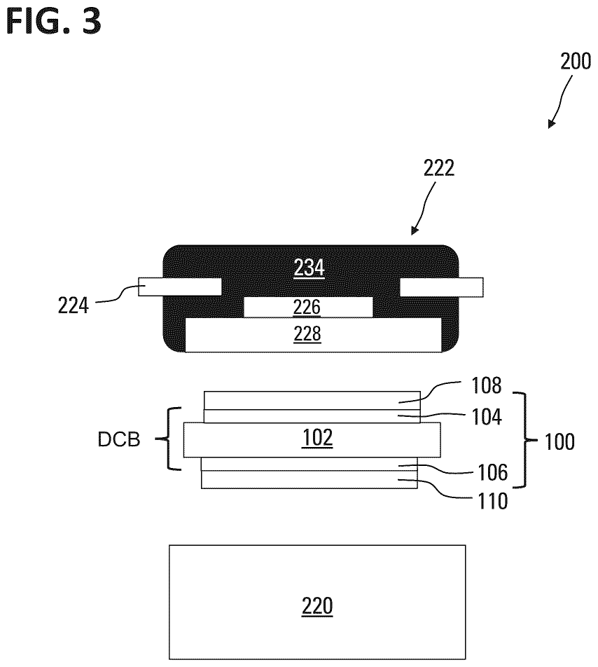

For example, as shown in FIG. 2B, a chip package 222 may be brought into thermal contact with a heat sink 220 via a carrier 103 (a core 102 of electrically insulating material, for example an organic foil that has a metal layer 104 and 106, respectively, on each of its main sides), and via a thermal interface material (TIM) 232 like for example a thermal grease, a thermal paste or a phase change material that is arranged between the chip package 222 and the carrier 103, and between the carrier 103 and the heat sink 220. To achieve such an arrangement, the chip package 222 may not need to be exposed to temperatures above, e. g., room temperature (e. g., 25° C.).

However, the thermal interface material 232, e. g., the thermal paste, may dry out or be subject to a so-called pump-out-effect, which may degrade the thermal performance of the arrangement over time. Furthermore, the TIM may have a comparatively high thermal resistance Rth (see the table below comparing thermal conductivities for various thermal interface arrangements).

A similar example of the prior art, with a ceramic core 102 without metal layers, is shown in FIG. 4D.

In another example of the prior art, silver platings (which may be referred to as active metal brazed AMB or brazed plate metal BPM) may be provided, for example on an eletrically insulating core 102, to enable sintering of devices (e. g., chip package 222) to a heat sink 220. An exemplary configuration is shown in FIG. 4C.

However, such an arrangement may require pressure and temperature for joining the chip package 222 and the heat sink 220, which may lead to a damage to the chip package 222.

In various embodiments, a carrier structure is provided. The carrier structure may include an electrically insulating carrier with metal layers on both main sides, and pre-applied solder on both metal layers.

The pre applied solder (e. g., Sn based, diffusion solder) may allow in various embodiments to bring down a complexity at customer side. In other words, the carrier structure may be ready for use (no solder application by the customer necessary).

In particular, in a case where the pre-applied solder is a diffusion solder, no pressure may be required for attaching a chip package and/or a heat sink, only heat. Thereby, mechanical damages to the chip package may be avoided or alleviated, thereby increasing the yield and/or a reliability of the resulting package arrangement.

A package arrangement that includes the carrier structure in accordance with various embodiments may be provided. In other words, the carrier structure may have the chip package pre-applied to the carrier structure, for example via a diffusion solder, and a re-melting solder layer (e. g., a standard tin-based solder) may be pre-applied to the side of the carrier structure that is opposite the chip package and can be used in a standard surface mounted device (SMD) line.

The metal layers of the carrier may in various embodiments include direct copper bonded layers. The electrically insulating core may for example be or include an electrically insulating material like a ceramic or organic material with a high thermal conductivity.

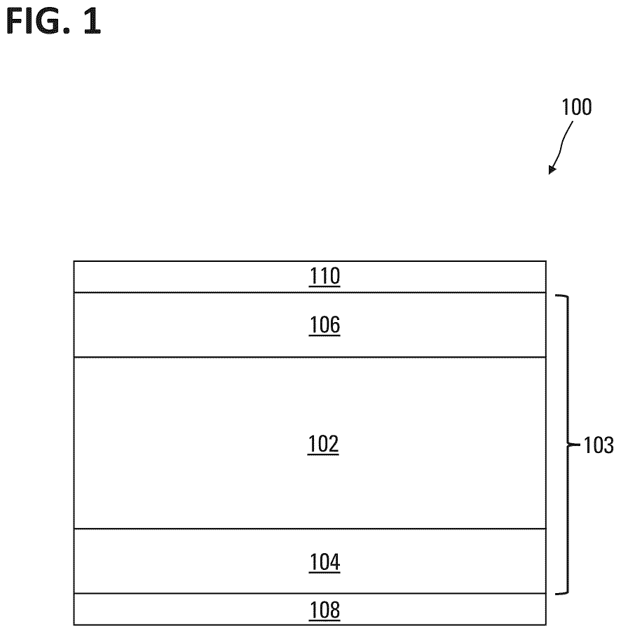

FIG. 1 shows a schematic cross-sectional view of a carrier structure 100 in accordance with various embodiments.

The carrier structure 100 may include an electrically insulating carrier 103, wherein the carrier 103 is thermally conductive, the carrier 103 including a core 102 of an electrically insulating material.

The core 102 may for example include or consist of a ceramic material like, e. g., AlN, Al₂O₃, or Si₃N₄, an organic material like for example polyvinyl chloride (PVC), all variants of epoxy based materials, or combinations thereof, for example as stacked layers etc.

The carrier 103 may further include a first metal layer 104 applied to a first side of the core 102, and a second metal layer 106 applied to a second side of the core 102, wherein the second side is opposite the first side.

The first metal layer 104 and/or the second metal layer 106 may for example include or consists of copper, Ni, Ni/P or NiPdAu. In a case of the core 102 including the ceramic material, the copper layer(s) 104 and/or 106 may for example include or consist of direct copper bonded material. In a case of the core 102 including the organic material, the copper layer(s) 104 and/or 106 may for example include or consist of deposited copper layers.

Other metal materials and/or metal application processes may be applied as required.

The first metal layer 104 and the second metal layer 106 may include or consist of the same or different materials.

The metal layers 104, 106 may have a thickness in a range from about 5 μm to about 2 mm, for example in a range from about 200 μm to about 800 μm.

The first metal layer 104 and/or the second metal layer 106 may in various embodiments completely cover their respective main surface of the core 102. Even though FIG. 1 shows only a cross-sectional view, this may for example be the case for the carrier structure 100 of FIG. 1. In various embodiments, the first metal layer 104 and/or the second metal layer 106 may cover their respective main surface of the core 102 only partially. A respective embodiment, where only a respective central portion of the main surface of the core 102 is covered by the metal layer 104 and 106, respectively, is shown in FIG. 2A. An arrangement of the first metal layer 104 and the second metal layer 106 may in various embodiments be symmetric with respect to a central plane of the core 102, in order to avoid warpage of the carrier structure 100 in a simple way. As an alternative, a surface portion covered and a structure, a material and a thickness of the first metal layer 104 and the second metal layer 106 may differ and be adjusted in such a way as to avoid warpage of the carrier structure 100 after manufacture and/or during thermal cycling.

The carrier structure 100 may further include a first exposed solder layer 108 on the first metal layer 104, and a second exposed solder layer 110 on the second metal layer 106.

The first solder layer 108 and the second solder layer 110 may include or consist of a diffusion solder, a preform reflow solder, or a combination thereof (for example, a diffusion solder as the first solder layer 108, and a reflow solder (e. g., a NiSn-solder) as the second solder layer 110).

The diffusion solder material of the first solder layer 108 and/or the second solder layer 110 may include or consist of at least one of a group of diffusion solders, the group including or consisting of nickel-tin, copper-tin, silver-tin, gold-tin, and palladium-tin.

The first solder layer 108 and/or the second solder layer 110 may in various embodiments completely cover their respective main surfaces of the first metal layer 104 and the second metal layer 106, respectively. Even though FIG. 1 shows only a cross-sectional view, this may for example be the case for the carrier structure 100 of FIG. 1, and also for the carrier structure 100 included in FIG. 2A. In various embodiments, the first solder layer 108 and/or the second solder layer 110 may cover their respective surface of the first metal layer 104 only partially (not shown). An arrangement of the first solder layer 108 and the second solder layer 110 may in various embodiments be symmetric with respect to a central plane of the core 102, in order to avoid warpage of the carrier structure 100 in a simple way. As an alternative, a surface portion covered and a structure, a material and a thickness of the first solder layer 108 and the second solder layer 110 may differ and be adjusted in such a way as to avoid warpage of the carrier structure 100 after manufacture and/or during thermal cycling.

The carrier structure 100 may in various embodiments be configured as a carrier for chip packages and heat sinks. In particular, the carrier structure 100 may be configured to be arranged between the chip package and the heat sink as a structural support, electrical insulation, and thermal interface.

In various embodiments, a package arrangement 200 is provided that includes the carrier structure 100 in accordance with various embodiments, for example as described above, e. g. with reference to FIG. 1.

In other words, the carrier structure 100 may serve as an intermediary electrically insulating support structure and provide solder connections for attaching the heat sink 220 to a chip package 222. Instead of a heat sink 220, the carrier structure 100 may enable attaching the chip package 222 to a printed circuit board. In other words, the heat sink 222 may be replaced by a PCB.

In various embodiments, for example as shown in FIG. 2A and 2B, the package arrangement 200 may be mounted on a board 230, e. g., a PCB, with the packaging material 234 facing the board 230.

FIG. 2A shows an exemplary embodiment of the package arrangement 200 that includes the carrier structure 100, the heat sink 220, and a chip package 222.

The chip package 222 may for example include a chip 226 mounted on a metal carrier 228, e.g., a leadframe, packaging material 234 encapsulating the chip 226 and partially encapsulating the metal carrier 228 (which means that at least a portion of the metal carrier 228 is exposed to ambient and configured to serve as a heat sink and/or to be attached to the heat sink 220, and optional leads 224 protruding from the packaging material 234 for electrically contacting the chip 226 (a no-leads package may for example be used instead of the shown chip package 222 having the protruding leads 224).

The metal carrier 228 may optionally be configured as an electrical contact for contacting the chip 226.

The chip package 222 may essentially be known in the art. It may however be necessary that the chip package 222 is configured to withstand the temperatures applied during a soldering process, for example during the soldering of the chip package 222 to the carrier structure 100, and/or during the soldering of the heat sink 220 to the carrier structure 100, for example during a diffusion soldering process that may require a temperature of, c. g., 250° C. or more for about 10 seconds.

Chip packages 222 that fulfill this requirement include each of the following: AG-62MMES, AG-EASY2B, AG-ECONO4, AG-ECONOD, AG-ECONOPP, AG-HYBRIDL, AG-IHVB190, AG-XHP3K33, BG-PB501, BG-PB50ND, BG-PB50SB, LG-MLGA, PG-MDIP, PG-SIP, C-CGA, C-FP, CG-FP, C-LCC, CG-LCC, P-LCC, PG-LCC, CG-LGA, CG-SSOP, PG-SSOP, CG-TSOP, PG-TSOP, LG-UIQFN, LG-WIQFN, MG-WDSON, P-BGA, PG-BGA, P-DSO, PG-DSO, P-LFBGA, PG-LFBGA, P-SOT143, PG-SOT143, P-SOT223, PG-SOT223, P-TFBGA, PG-TFBGA, P-TO252, PG-TO252, P-TO263, PG-TO263, P-TQFP, PG-TQFP, P-TSSOP, PG-TSSOP, P-VFBGA, PG-VFBGA, PG-ATSLP, PG-DFN, PG-DSOF, PG-DSOSP, PG-FBGA, PG-FCBGA, PG-FHBGA, PG-HDSOP, PG-HSOF, PG-HSOG, PG-IQFN, PG-LBGA, PG-LDSO, PG-LHSOF, PG-LHSOG, PG-LLGA, PG-LQFP, PG-LSON, PG-MQFP, PG-SC59, PG-SC74, PG-SC79, PG-SCT595, PG-SOD323, PG-SOJ, PG-SOT23, PG-SOT323, PG-SOT 343, PG-SOT 363, PG-SOT 89, PG-TDSO, PG-TDSON, PG-TFLGA, PG-TIQFN, PG-TISON, PG-TLGA, PG-TSDSO, PG-TSDSON, PG-TSFP, PG-TSLP, PG-TSNP, PG-TSON, PG-TSOP6, PG-TSSLP, PG-TTFN, PG-UF2BGA, PG-UFLGA, PG-ULGA, PG-UQFN, PG-USON, PG-VDSON, PG-VF2BGA, PG-VFWLB, PG-VIQFN, PG-VITFN, PG-VLGA, PG-VQFN, PG-VSON, PG-WF2BGA, PG-WFWLB51 SG-WFWLB, PG-WHITFN, PG-WHSON, PG-WHTFN, PG-WISON, PG-WLGA, PG-WSON, PG-X2QFN, PG-XSON, SG-FWLP, SG-UFWLB, SG-WLL, SG-XFWLB, C-DIP, PG-DIP, PG-HSIP247, PG-SSO, PG-SSOA11, PG-SSOM, PG-TO220, PG-TO247, PG-TO251, and PG-TO262.

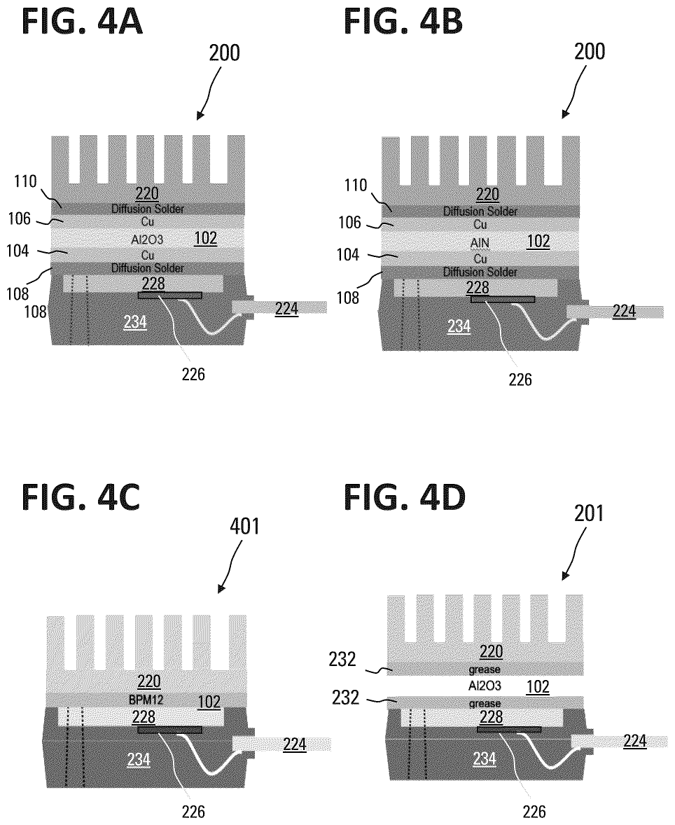

In various embodiments, as shown in FIG. 3, which shows a schematic cross-sectional, partially exploded view of a package arrangement 200 in accordance with various embodiments, the carrier 100, the heat sink 220, and the chip package 222 may initially form three separate entities, which may be joined by the customer, for example in a single (e. g., diffusion soldering) process, or for example in two or more successive processes, for example by first attaching the chip package 222, and subsequently the heat sink 220 (or vice versa), to the carrier structure 100 using soldering.

As an alternative, for example the carrier structure 100 and the chip package 222 may be pre-joined (e. g., by diffusion soldering).

Even though the diffusion solder 108 may initially melt at a temperature that lies in a range from about 200° C. to about 300° C., e.g., about 230° C., after hardening, the melting temperature may be increased to above that value, for example to about 400° C., and in particular to a value higher than the melting point of the second solder layer 110, which may for example be around 240° C. This means that the second soldering process (e. g., for attaching the heat sink 222) may be executed without re-melting the solder joint between the chip package 222 and the carrier structure 100.

Furthermore, the solder connection may have a very high reliability and a very low thermal resistivity, in particular in comparison with, e. g., a thermal paste. If the diffusion solder is used, a further advantage is the pressure-free assembly process that may be applied.

Some aspects of materials, material combinations etc include the following:

In case of a diffusion solder for the first solder layer 108 and/or the second solder layer 110, a minimum thickness of the first metal layer 104 and/or of the second metal layer 106 may be around 50 μm (of DCB) to avoid a warpage of the carrier structure 100. A thickness of the (e. g., AlN) core 102 may be in a range from about 20 μm to about 30 μm.

In another exemplary embodiment, the carrier structure 100 may include a tri-layer-foil including a PVC core 102 with a thickness of about 100 μm to about 200 μm, and Cu-layer(s) 104 and/or 106 of about 15 μm thickness each.

On the DCB metal layers 104, 106 that may be formed on the ceramic (e. g., Al₂O₃, AlN, Si3N4, . . . ), a NiSn solder may be used for the first solder layer 108 and/or the second solder layer 110.

Diffusion solder systems that may be used as the first solder layer 108 and/or the second solder layer 110 include the following: DCB/AMB with bare Cu, Ni-plating, NiP-plating and/or noble metal plating (Ag, Au, PT, Pd) in combination with Sn or a Sn-based solder material (SnAg, SAC, SnSb, AuSn), In or In-rich solder material, and a combination of both (e.g. 48Sn52In), which may allow for a melting temperature of 120° C.

In various embodiments, a surface of the first solder layer 108 and/or of the second solder layer 110, which may for example include NiSn, may be protected by an additional Au, Ag, Pt, and/or Pd flash on top of the first (e. g., diffusion) solder layer 108 and/or of the second (e. g., diffusion) solder layer 110.

In various embodiments, a Sn surface may optionally not require a protection layer, since the Sn may self-passivate.

In the following, specific or exemplary properties of various materials are summarized:

| | Thermal | Typical |
|---|---|---|
| Material | Conductivity [W/mK] | thickness [μm] |
| Thermal grease/Phase change | 1-3 | 30-100 μm |
| Al₂O₃ DCB | 24 | 180-600 |
| AlN DCB | 180 | 180-600 |
| Si₃N₄ AMB | 70 | 180-600 |
| Diffusion solder | 70 | 12 |

In particular, the comparatively high thermal conductivity of the diffusion solder connection as compared with the thermal grease material may be noted.

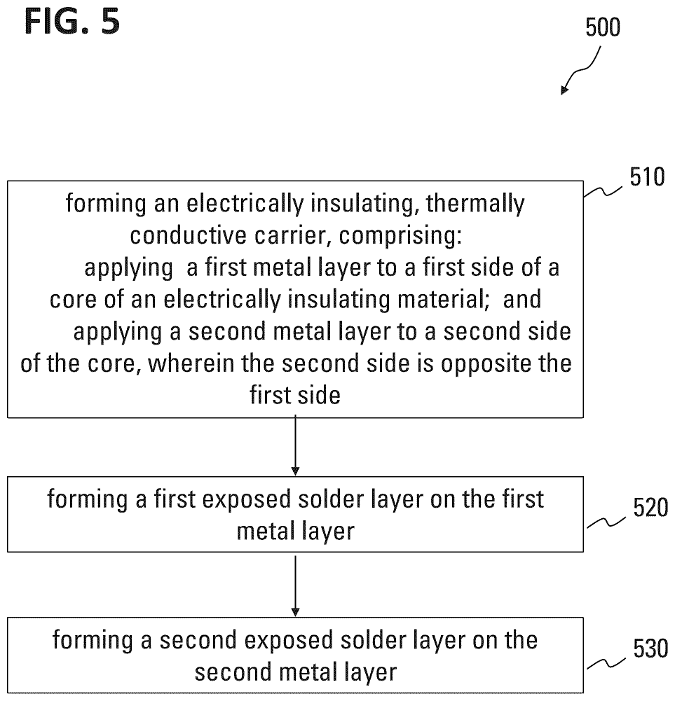

FIG. 5 shows a flow diagram 500 of a method of forming a carrier structure that includes an electrically insulating carrier, wherein the carrier is thermally conductive, in accordance with various embodiments.

The method may include forming the carrier, including applying a first metal layer to a first side of a core of an electrically insulating material and applying a second metal layer to a second side of the core, wherein the second side is opposite the first side (510), forming a first exposed solder layer on the first metal layer (520), and forming a second exposed solder layer on the second metal layer (530).

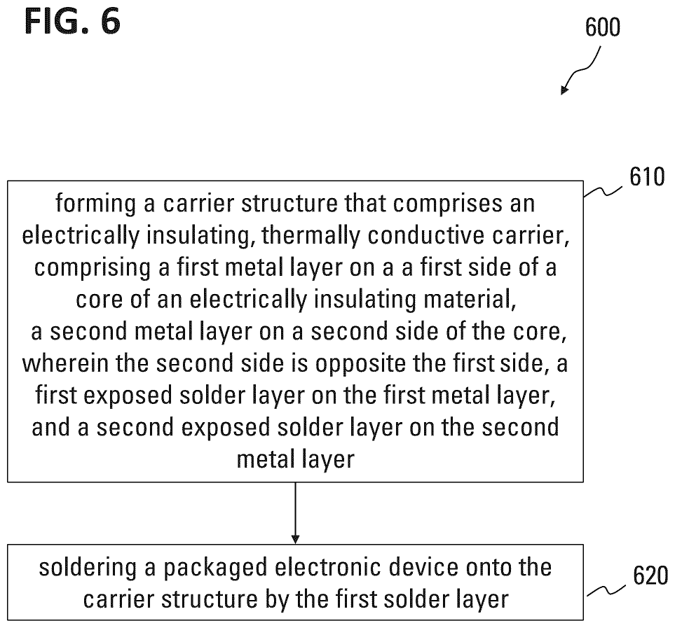

FIG. 6 shows a flow diagram 600 of a method of forming a package arrangement in accordance with various embodiments.

The method may include forming a carrier structure that comprises an electrically insulating, thermally conductive carrier, comprising a first metal layer on a a first side of a core of an electrically insulating material, a second metal layer on a second side of the core, wherein the second side is opposite the first side, a first exposed solder layer on the first metal layer, and a second exposed solder layer on the second metal layer (610), and soldering a chip package onto the carrier structure by the first solder layer (620).

Various examples will be illustrated in the following:

Example 1 is a carrier structure. The carrier structure may include an electrically insulating carrier, wherein the carrier is thermally conductive, the carrier including a core of an electrically insulating material, a first metal layer applied to a first side of the core, and a second metal layer applied to a second side of the core, wherein the second side is opposite the first side, a first exposed solder layer on the first metal layer, and a second exposed solder layer on the second metal layer.

In Example 2, the subject-matter of Example 1 may optionally include that the carrier is configured as a direct copper bonding structure.

In Example 3, the subject-matter of Example 1 or 2 may optionally include that the metal of the first metal layer and/or of the second metal layer includes or consists of copper, Ni, Ni/P or NiPdAu

In Example 4, the subject-matter of any of Examples 1 to 3 may optionally include that a material of the first solder layer and/or a material of the second solder layer includes a diffusion solder.

In Example 5, the subject-matter of Example 4 may optionally include that the diffusion solder includes at least one of a group of diffusion solders, the group including or consisting of nickel-tin, copper-tin, silver-tin, gold-tin, and palladium-tin.

In Example 6, the subject-matter of any of Examples 1 to 5 may optionally include that the electrically insulating material includes or consists of an organic material and/or a ceramic material.

In Example 7, the subject-matter of any of Examples 1 to 6 may optionally include that the electrically insulating material includes at least one of a group of materials, the group including or consisting of Al₂O₃, AlN, and Si₃N₄.

Example 8 is a package arrangement. The package arrangement may include a carrier structure according to any of Examples 1 to 7, and a chip package mounted on the carrier structure, wherein the chip package is soldered to the carrier structure by the first solder layer.

Example 8 a is a package arrangement. The package arrangement may include a carrier structure that may include an electrically insulating carrier, wherein the carrier is thermally conductive, the carrier including a core of an electrically insulating material, a first metal layer applied to a first side of the core, and a second metal layer applied to a second side of the core, wherein the second side is opposite the first side, a first solder layer on the first metal layer, and a second exposed solder layer on the second metal layer. The package arrangement may further include a chip package mounted on the carrier structure, wherein the chip package is soldered to the carrier structure by the first solder layer.

In Example 9, the subject-matter of Example 8 may optionally include that the first solder layer and/or the second solder layer has a melting temperature of 200° C. or higher, e. g., of 300° C. or higher, e.g., about 400° C.

In Example 10, the subject-matter of any of Examples 8 to 9 may optionally include that the chip package includes a metal carrier, wherein an exposed surface of the metal carrier may be soldered to the carrier structure by the first solder layer.

In Example 11, the subject-matter Example 10 may optionally include that at least one semiconductor device, for example a semiconductor chip, e. g. a chip, is connected to the second surface of the metal carrier.

In Example 12, the subject-matter of any of Examples 10 to 11 may optionally include that the metal carrier is partially encapsulated by packaging material.

In Example 13, the subject-matter of any of Examples 8 to 12 may optionally further include a heat sink soldered to the carrier structure by the second solder layer.

In Example 14, the subject-matter of any of Examples 8 to 12 may optionally further include a printed circuit board (PCB) soldered to the carrier structure by the second solder layer.

Example 15 is a method of forming a carrier structure that includes an electrically insulating carrier, wherein the carrier is thermally conductive. The method may include forming the carrier, including applying a first metal layer to a first side of a core of an electrically insulating material and applying a second metal layer to a second side of the core, wherein the second side is opposite the first side, forming a first exposed solder layer on the first metal layer, and forming a second exposed solder layer on the second metal layer.

In Example 16, the subject-matter of Example 15 may optionally include that the applying the first metal layer and/or the applying the second metal layer includes or consists of direct copper bonding.

In Example 17, the subject-matter of Example 15 or 16 may optionally include that the metal of the first metal layer and/or of the second metal layer includes or consists of copper, Ni, Ni/P or NiPdAu

In Example 18, the subject-matter of any of Examples 15 to 17 may optionally include that a material of the first solder layer and/or a material of the second solder layer includes a diffusion solder.

In Example 19, the subject-matter of any of Examples 15 to 18 may optionally include that the diffusion solder includes at least one of a group of diffusion solders, the group including or consisting of nickel-tin, copper-tin, silver-tin, gold-tin, and palladium-tin.

In Example 20, the subject-matter of any of Examples 15 to 19 may optionally include that the electrically insulating material includes or consists of an organic material and/or a ceramic material.

In Example 21, the subject-matter of any of Examples 15 to 20 may optionally include that the electrically insulating material includes at least one of a group of materials, the group including or consisting of Al₂O₃, AlN, and Si₃N₄.

Example 22 is a method of forming a package arrangement. The method may include forming a carrier structure in accordance with any of Examples 15 to 21, and soldering a chip package onto the carrier structure by the first solder layer.

In Example 23, the subject-matter of Example 22 may optionally include that the first solder layer and/or the second solder layer has a melting temperature of 200° C. or higher, e. g., of 300° C. or higher, e.g., about 400° C.

In Example 24, the subject-matter of Example 22 or 23 may optionally include that the soldering includes a pressure-free solder process.

In Example 25, the subject-matter of any of Examples 22 to 24 may optionally include that the soldering the chip package onto the carrier structure includes soldering an exposed surface of a metal carrier onto the carrier structure.

In Example 26, the subject-matter of Example 24 may optionally include that the chip package includes at least one semiconductor device connected to a second surface of the metal carrier.

In Example 27, the subject-matter of any of Examples 25 or 26 may optionally include that the metal carrier is partially encapsulated by an encapsulation.

In Example 28, the subject-matter of any of Examples 25 to 27 may optionally further include soldering a heat sink to the carrier structure by the second solder layer.

In Example 29, the subject-matter of any of Examples 25 to 27 may optionally further include soldering a printed circuit board (PCB) to the carrier structure by the second solder layer.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A package arrangement, comprising:
a carrier structure, comprising:
an electrically insulating carrier, wherein the carrier is thermally conductive, the carrier comprising:
a core of an electrically insulating material;
a first metal layer applied to a first side of the core; and
a second metal layer applied to a second side of the core, wherein the second side is opposite the first side; and
a first exposed solder layer on the first metal layer; and
a chip package mounted on the carrier structure;
wherein the chip package is soldered to the carrier structure by the first solder layer;
wherein the chip package comprises a metal carrier, wherein an exposed surface of the metal carrier is soldered to the carrier structure by the first solder layer.

2. The package arrangement according to claim 1,
wherein the carrier structure further comprises a second exposed solder layer on the second metal layer.

3. The package arrangement according to claim 1,
wherein the carrier is configured as a direct copper bonding structure.

4. The package arrangement according to claim 1,
wherein the metal of the first metal layer and/or of the second metal layer comprises or consists of copper, Ni, Ni/P or NiPdAu.

5. The package arrangement according to claim 1,
wherein a material of the first solder layer and/or a material of the second solder layer comprises a diffusion solder.

6. The package arrangement according to claim 5,
wherein the diffusion solder comprises at least one of a group of diffusion solders, the group consisting of:
nickel-tin;
copper-tin;
silver-tin;
gold-tin; and
palladium-tin.

7. The package arrangement according to claim 1,
wherein the electrically insulating material comprises or consists of an organic material and/or a ceramic material.

8. The package arrangement according to claim 1,
wherein the electrically insulating material comprises at least one of a group of materials, the group consisting of:
Al₂O₃;
AlN; and
Si₃N₄.

9. The package arrangement according to claim 1,
wherein the first solder layer and/or the second solder layer has a melting temperature of 200° C. or higher.

10. The package arrangement according to claim 1,
wherein at least one semiconductor device is connected to the second surface of the metal carrier.

11. The package arrangement according to claim 1,
wherein the metal carrier is partially encapsulated by packaging material.

12. The package arrangement according to claim 1, further comprising:
a heat sink soldered to the carrier structure by the second solder layer.

13. The package arrangement according to claim 1, further comprising:
a printed circuit board (PCB) soldered to the carrier structure by the second solder layer.

14. A method of forming a package arrangement, the method comprising:
forming a carrier structure that comprises an electrically insulating carrier, wherein the carrier is thermally conductive, the method comprising:
forming the carrier, comprising:
applying a first metal layer to a first side of a core of an electrically insulating material; and
applying a second metal layer to a second side of the core, wherein the second side is opposite the first side;
forming a first exposed solder layer on the first metal layer; and
soldering a chip package onto the carrier structure by the first solder layer; and
wherein the soldering the chip package onto the carrier structure comprises soldering an exposed surface of a metal carrier onto the carrier structure.

15. The method according to claim 14, wherein the forming the carrier structure further comprises:
forming a second exposed solder layer on the second metal layer.

16. The method according to claim 14,
wherein the applying the first metal layer and/or the applying the second metal layer comprises or consists of direct copper bonding.

17. The method according to claim 14,
wherein the metal of the first metal layer and/or of the second metal layer comprises or consists of copper, Ni, Ni/P or NiPdAu.

18. The method according to claim 14,
wherein a material of the first solder layer and/or a material of the second solder layer comprises a diffusion solder.

19. The method according to claim 18,
wherein the diffusion solder comprises at least one of a group of diffusion solders, the group consisting of:
nickel-tin;
copper-tin;
silver-tin;
gold-tin; and
palladium-tin.

20. The method according to claim 14,
wherein the electrically insulating material comprises or consists of an organic material and/or a ceramic material.

21. The method according to claim 14,
wherein the electrically insulating material comprises at least one of a group of materials, the group consisting of:
Al₂O₃;
AlN; and
Si₃N₄.

22. The method according to claim 14,
wherein the first solder layer, after the soldering, has a melting temperature of 200° C. or higher.

23. The method according to claim 14,
wherein the soldering comprises a pressure-free solder process.

24. The method according to claim 14,
wherein the chip package comprises at least one semiconductor device connected to a second surface of the metal carrier.

25. The method according to claim 14,
wherein the metal carrier is partially encapsulated by an encapsulation.

26. The method according to claim 14, further comprising:
soldering a heat sink to the carrier structure by the second solder layer.

27. The method according to claim 14, further comprising:
soldering a printed circuit board (PCB) to the carrier structure by the second solder layer.
